(19) United States
(12) Patent Application Publication
(10) Pub. No.: US 2024/0410918 A1
(43) Pub. Date: Dec. 12, 2024

(54) PROBE CARD STRUCTURE FOR HIGH FREQUENCY TEST AND TESTING METHOD THEREOF

(71) Applicant: STAR TECHNOLOGIES, INC., HSINCHU CITY (TW)

(72) Inventor: CHOON LEONG LOU, SINGAPORE (SG)

(21) Appl. No.: 18/541,001

(22) Filed: Dec. 15, 2023

(30) Foreign Application Priority Data
Jun. 9, 2023 (TW) 112121516

(51) Int. Cl. G01R 1/067; G01R 1/073; G01R 31/28

(52) U.S. Cl. CPC G01R 1/06772; G01R 1/06755; G01R 1/07314; G01R 31/2837

(57) ABSTRACT

A probe card structure for high frequency test is provided. The probe card structure includes a circuit board, a silicon substrate, and a probe head assembly. The silicon substrate is disposed on a side of the circuit board and electrically connected to the circuit board. A signal processing circuit is disposed on the silicon substrate. The probe head assembly includes a plurality of probes that are correspondingly and electrically connected to the silicon substrate.

### CROSS-REFERENCE TO RELATED PATENT APPLICATION

This application claims the benefit of priority to Taiwan Patent Application No. 112121516, filed on Jun. 9, 2023. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a probe card structure and a testing method thereof, and more particularly to a probe card structure for high frequency test and a testing method thereof.

### BACKGROUND OF THE DISCLOSURE

In existing wafer testing, an automated test equipment (ATE) is coupled to a wafer probe tester, so that a testing signal is provided a device under test through probes and a probe card. In addition, a response of a test object to the testing signal is measured to determine whether or not an operation and/or performance of the device under test are normal. However, a lone line connecting the probe card to the ATE is unfavorable for high-speed transmission, and it also requires more space for the long line, which will have adverse effects.

In addition, in order to be suitable for smaller wafer size, an adaptor board or a space transformer (e.g., a multi-layer organic, MLO) is utilized to shorten a pitch between the probes in conventional technology. However, with the miniaturization of wafers, the adaptor board or the space transformer is not able to provide even smaller pitch due to the limitations of process capabilities, which cannot meet the pitch requirements between test points for the miniaturized wafer. The limited pitch provided by the adaptor board or the space transformer leads to that a contact between the probe and a contact point is limited, thereby prolonging the test time and reducing the test efficiency. Moreover, a signal path cannot be further shortened, causing that interference cannot be effectively minimized during transmitting the signals.

Therefore, how to provide an innovative design for probe card structure to enable the adaptor board or the space transformer to provide smaller pitch, and how to speed up the test speed of the probe card for high frequency testing to shorten the signal transmission path and reduce an impact of signal interference, to overcome the above issues has become one of the important issues to be addressed in the related field.

### SUMMARY OF THE DISCLOSURE

In response to the above-referenced technical inadequacies, the present disclosure provides a probe card structure for high frequency test, which includes a circuit board, a silicon substrate, a probe head assembly, and a signal processing circuit. The silicon substrate is disposed on a side of the circuit board and electrically connected to the circuit board. The probe head assembly including a plurality sets of probes that are vertical probes for receiving a high-frequency signal of a device under test. The probe head assembly is configured to transmit the high frequency signal to the silicon substrate. The signal processing circuit is disposed on the silicon substrate and configured for processing the high frequency signal into an output signal and transmitting the output signal to a tester.

In one of the possible or preferred embodiments, the signal processing circuit is an active component or a passive component.

In one of the possible or preferred embodiments, the signal processing circuit is a power supply, an amplifier, an oscillator, a digital signal processor, or an analog signal converter.

In one of the possible or preferred embodiments, the signal processing circuit includes a first circuit element, a second circuit element, and a third circuit element.

In one of the possible or preferred embodiments, each of the plurality sets of probes has a first contact end and a second contact end that are opposite to each other, the first contact end is electrically connected to the silicon substrate, the second contact end is in contact with the device under test, and the silicon substrate and the device under test have a same material property.

In one of the possible or preferred embodiments, an electrical signal from the device under test is processed by the signal processing circuit on the silicon substrate without passing through the circuit board.

In one of the possible or preferred embodiments, a pitch between two probes is less than 40 μm.

In one of the possible or preferred embodiments, a surface of the silicon substrate facing the circuit board is provided with a plurality of solder balls, and a material of each of the plurality of solder balls is metal or alloy.

In one of the possible or preferred embodiments, each of the plurality sets of probes is made of a material selected from a group consisting copper, palladium, silver, gold, platinum, tungsten, germanium, tungsten-rhenium alloy, beryllium copper alloy, palladium gold alloy, palladium silver alloy, tungsten carbide, and alloys thereof.

In order to solve the above-mentioned problems, one of the technical aspects adopted by the present disclosure is to provide a method for testing high frequency signal, which includes: receiving a high frequency signal from a device under test using a probe head assembly; wherein the probe head assembly includes a plurality sets of probes that are vertical probes, for transmitting the high frequency signal to a silicon substrate; and processing the high frequency signal into an output signal using a signal processing circuit on the silicon substrate, and transmitting the output signal to a tester.

Therefore, one of the beneficial effects of the present disclosure is that, in the probe card structure for high frequency test provided by the present disclosure, by virtue of “the probe head assembly for receiving the high frequency signal of the device under test, and the probe head assembly being configured to transmit the high-frequency signal to the silicon substrate” and “the signal processing circuit being disposed on the silicon substrate and configured for processing the high-frequency signal into the output signal and transmitting the output signal to the tester,” the processing speed of the probe card can be accelerated, and the interference caused by the long paths can be avoided, such that the probe card can be more suitable for high frequency transmission.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of a probe card structure according to one embodiment of the present disclosure; and

FIG. 2 is a schematic side view of a probe card structure according to another embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### EMBODIMENTS

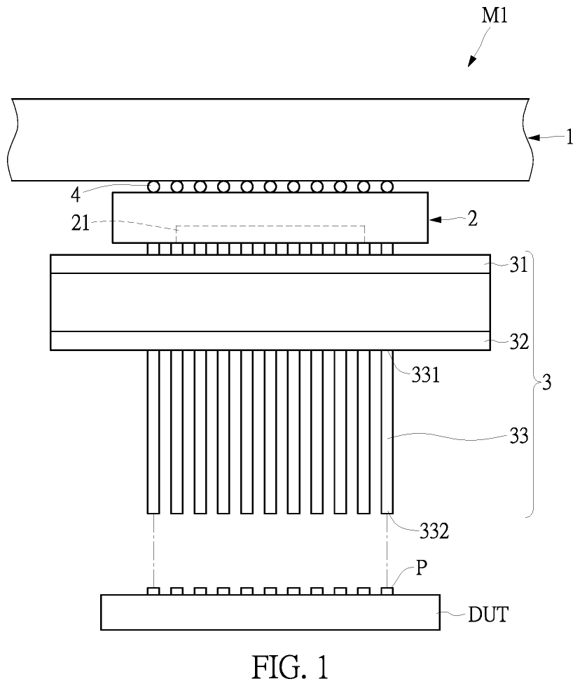

Referring to FIG. 1, a probe card structure M1 of the present disclosure includes a circuit board 1, a silicon substrate 2, and a probe head assembly 3. The circuit board 1 can be a printed circuit board (PCB) or a flexible printed circuit board (FPCB). However, the aforementioned example is merely an example, and is not meant to limit the scope of the present disclosure. In the probe card structure M1 of the present disclosure, the silicon substrate 2 is disposed on a side of the circuit board 1, and the silicon substrate 2 can be electrically connected to the circuit board 1.

The silicon substrate 2 of the present disclosure can be used as an adapter board or a space transformer. Compared with adapter boards or space transformer made from the PCB, the adapter or the space transformer using the silicon substrate can provide a smaller pitch between probes. It is worth mentioning that, a signal processing circuit 21 can be not disposed on the PCB due to cost and size considerations, so it is preferable to adopt a silicon wafer for the silicon substrate 2 of the present disclosure. Since the silicon substrate 2 of the present disclosure is made of a silicon-based material, the signal processing circuit 21 can be disposed on the silicon substrate 2, and the signal processing circuit 21 can be an active component or a passive component. For example, a material of the silicon substrate 2 can include silicon nitride or silicon carbide. That is, the material of the silicon substrate 2 can be the same as a material of a device under test DUT, such that the silicon substrate 2 has the same material property as the device under test DUT. In this way, since a plurality of probes 33 of the probe head assembly 3 are correspondingly and electrically connected to the silicon substrate 2, and the silicon substrate 2 has the same material property as the device under test DUT, an offset of a electrically conductive contact P is the same as an offset of the plurality of probes 33 when the electrically conductive contact P on a surface of the device under test DUT is displaced due to thermal expansion, thereby improving alignment accuracy of the plurality of probes 33.

For example, the signal processing circuit 21 may include a power supply, an amplifier, an oscillator, a digital signal processor (DSP), or an analog signal converter, such that a signal processing for the device under test DUT can be directly performed on the silicon substrate 2 without wiring through the circuit board 1 to transmit an electrical signal to a tester outside the probe structure M1. In other words, the electrical signal measured from the device under test DUT does not pass through the circuit board 1. It should be noted that, the present disclosure does not specifically limit a type of the signal processing circuit 21 as long as the electrical signal of the device under test DUT can be tested directly on the silicon substrate 2. In other words, high frequency signals detected by the plurality of probes form the device under test DUT are transmitted to the signal processing circuit 21 of the silicon substrate 2, and different sets of probes correspond to different sets of signal processing circuits 21, so that different sets of signal processing circuits 21 can process the signals from the different sets of probes. The high frequency signals detected are processed through the signal processing circuits 21 on the silicon substrate 2, and processed results are then transmitted to the tester through the circuit board 1 and conductive wires to complete the test. During the signal processing process, the signal processing of the high frequency signals from the device under test DUT can be completed merely through the plurality of probes 33 and the signal processing circuit 21 of the silicon substrate 2, so that a transmission path of the high-frequency signals can be significantly shortened, which effectively reduces interference of the high frequency signals.

Further, the plurality of probes can be vertical probes. For example, the plurality of probes can be spring probes, such as vertical pogo pins. However, the present disclosure does not specifically limit a type of the probes 33 as long as such probes can be assembled on a probe card to test the device under test DUT. For example, each of the plurality of probes 33 can be an elastic structure that is capable of bending and deforming after being subjected to an axial force that exceed a critical load, so that the probe 33 is not easily broken due to compression by an external force. For example, the plurality of probes 33 each are made of a material selected from a group consisting copper, palladium, silver, gold, platinum, tungsten, germanium, tungsten-rhenium alloy, beryllium copper alloy, palladium gold alloy, palladium silver alloy, tungsten carbide, and alloys thereof. In one particular embodiment of the present disclosure, a pitch between the two probes 33 can be less than 40 μm so as to manufacture a probe card suitable for testing small wafers.

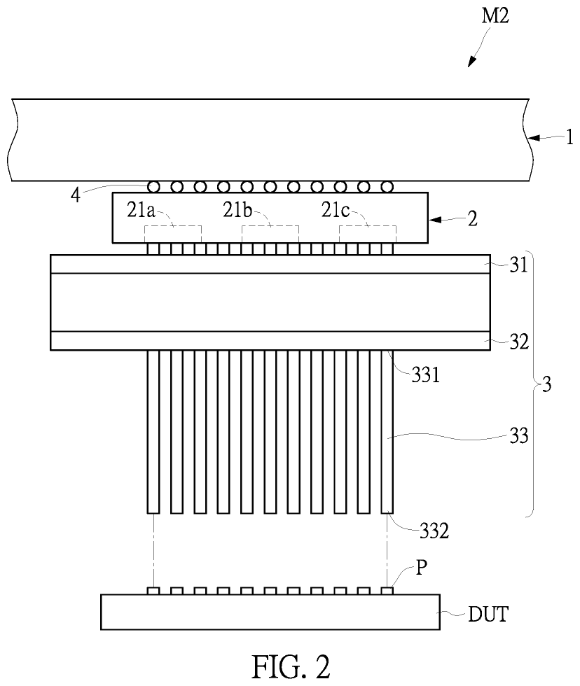

As shown in FIG. 2, in another embodiment of the present disclosure, in a probe card structure M2 of the present disclosure, the signal processing circuit 21 can include a first circuit element 21a, a second circuit element 21b, and a third circuit element 21c. For example, the first circuit element 21a is a resistor, the second circuit element 21b is a capacitor, and the third circuit element 21c is an inductor. That is, a resistance-inductance-capacitance (RLC) circuit can be disposed on the silicon substrate 2 and electrically connected to the plurality of probes so speed up the test. Accordingly, an electrical path can be also compensated (e.g., through impedance matching) in the present disclosure.

Specifically, the signal processing circuit 21 is disposed on the silicon substrate 2, such that a loop back structure is formed between the signal processing circuit 21 and the electrically conductive contact P of the device under test DUT. During the test, the electrical signals from the device under test DUT can be processed by the signal processing circuit 21 of the silicon substrate 2 without transmitting through the circuit board 1. Moreover, there is no need to set up additional wiring to transmit the electrical signals to an automatic tester outside of the probe card structure M2. Therefore, the processing of the electrical signals can be quickly performed, and interference caused by long paths can be avoided. In addition, the components required for a test device can be reduced and the cost can be lowered, which makes it particularly suitable for the high frequency testing field. That is, disposing the signal processing circuit 21 on the silicon substrate 2 can speed up a processing speed of the probe card test.

Further, the circuit board 1 and the silicon substrate 2 are electrically connected to each other through a plurality of solder balls 4. The silicon substrate 2 is electrically connected to the circuit board 1 through the plurality of solder balls 4 to securely solder the silicon substrate 2 to the circuit board 1. Further, a material of each of the plurality of solder balls 4 is metal or alloy. Preferably, the material of each of the plurality of solder balls 4 is tin, tin alloy, gold, or gold alloy. However, the aforementioned example is merely an example, and is not meant to limit the scope of the present disclosure.

Further, the probe head assembly 3 can include an upper guide plate 31, a lower guide plate, and the plurality of probes 33. The upper guide plate 31 and the lower guide plate are arranged parallel to each other, and respectively have a plurality of upper guide plate holes and a plurality of lower guide plate holes (not shown in the figures). The plurality of probes 33 pass through the upper guide plate 31 and the lower guide plate 32 correspondingly through the plurality of upper guide plate holes and the plurality of lower guide plate holes. In addition, each of the plurality of probes 33 is integrally formed from a conductor, and has a first contact end 331 and a second contact end 332 that are opposite to each other. The first contact end 331 is electrically connected to the silicon substrate 2, and the second contact end 332 is in contact with the electrically conductive contact P of the device under test DUT. For example, the probe 33 can be formed by a microelectromechanical process, electroforming, or laser cutting.

That is, the first contact end 331 of the probe 33 passes through a corresponding one of the plurality of upper guide plate holes of the upper guide plate 31 to be electrically connected to the silicon substrate 2, and the second contact end 332 of the probe passes through a corresponding one of the plurality of lower guide plate holes to be electrically connected to the electrically conductive contact P on the surface of the device under test DUT. For example, the electrically conductive contact P can be a solder pad, a bump, or a solder ball. It should be noted that a number of each of the upper guide plate 31 and the lower guide plate 32 of the present disclosure is not limited to one. In one particular embodiment of the present disclosure, the probe head assembly 3 can include multiple upper guide plates 31 and multiple lower guide plates 32.

The present disclosure provides a method for testing a high frequency signal, which includes step S100 and step S200. In step S100, the high frequency signal of the device under test DUT is received using the probe head assembly 3, which includes a plurality sets of vertical probes for transmitting the high frequency signal to the silicone substrate 2. In step S200, the high frequency signal is processed using the signal processing circuit 21 on the silicon substrate 2 into an output signal, and the output signal is transmitted to the tester. Compared to the existing high frequency test method that the high frequency signal is required to be transmitted to the tester for processing, in the method of the present disclosure the high frequency signal is directly processed through the signal processing circuit 21 on the silicon substrate 2, so that a shortest path for the high frequency signal can be provided, thereby avoiding interference caused by the high frequency signal passing through a long path.

### BENEFICIAL EFFECTS OF THE EMBODIMENTS

In conclusion, one of the beneficial effects of the present disclosure is that, in the probe card structure for high frequency test provided by the present disclosure, by virtue of “the probe head assembly for receiving the high frequency signal of the device under test, and the probe head assembly being configured to transmit the high-frequency signal to the silicon substrate” and “the signal processing circuit being disposed on the silicon substrate and configured for processing the high-frequency signal into the output signal and transmitting the output signal to the tester,” the processing speed of the probe card can be accelerated, and the interference caused by the long paths can be avoided, such that the probe card can be more suitable for high frequency transmission.

Further, at least one of the active component and the passive component is disposed on the silicon substrate of the probe card structure of the present disclosure, such that a loopback structure is formed between the at least one of the active component and the passive component, and the electrically conductive point of the device under test. In this way, it does not need to transmit the electrical signal measured from the device under test back to the automatic tester outside of the probe card structure through the line coupled to a wafer probe tester. Instead, the electrical signal can be processed through the loopback structure between the at least one of the active component and the passive component, and the electrically conductive point of the device under test, which can lead to acceleration of the processing speed. Furthermore, the interference caused by the long paths can be avoided, and the components required can be reduced and the cost can be lowered, which makes it particularly suitable for the high frequency testing field.

In addition, in the probe card structure of the present disclosure, since the plurality of probes are correspondingly and electrically connected to the silicon substrate, and the silicon substrate has the same material property as the device under test, the offset of the electrically conductive contact is the same as the offset of the plurality of probes the when the electrically conductive contact on the surface of the device under test is displaced due to thermal expansion, thereby improving the alignment accuracy of the plurality of probes.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A probe card structure for high frequency test, comprising:
a circuit board;
a silicon substrate disposed on a side of the circuit board and electrically connected to the circuit board;
a probe head assembly including a plurality sets of probes that are vertical probes for receiving a high frequency signal of a device under test; wherein the probe head assembly is configured to transmit the high-frequency signal to the silicon substrate; and
a signal processing circuit disposed on the silicon substrate and configured for processing the high frequency signal into an output signal and transmitting the output signal to a tester.

2. The probe card structure according to claim 1, wherein the signal processing circuit is an active component or a passive component.

3. The probe card structure according to claim 1, wherein the signal processing circuit includes a power supply, an amplifier, an oscillator, a digital signal processor, or an analog signal converter.

4. The probe card structure according to claim 1, wherein the signal processing circuit includes a first circuit element, a second circuit element, and a third circuit element.

5. The probe card structure according to claim 1, wherein each of the plurality sets of probes has a first contact end and a second contact end that are opposite to each other, the first contact end is electrically connected to the silicon substrate, the second contact end is in contact with the device under test, and the silicon substrate and the device under test have a same material property.

6. The probe card structure according to claim 5, wherein an electrical signal from the device under test is processed by the signal processing circuit on the silicon substrate without passing through the circuit board.

7. The probe card structure according to claim 1, wherein a pitch between two probes is less than 40 μm.

8. The probe card structure according to claim 1, wherein a surface of the silicon substrate facing the circuit board is provided with a plurality of solder balls, and a material of each of the plurality of solder balls is metal or alloy.

9. The probe card structure according to claim 1, wherein each of the plurality sets of probes is made of a material selected from a group consisting copper, palladium, silver, gold, platinum, tungsten, germanium, tungsten-rhenium alloy, beryllium copper alloy, palladium gold alloy, palladium silver alloy, tungsten carbide, and alloys thereof.

10. A method for testing high frequency signal, comprising:
receiving a high frequency signal from a device under test using a probe head assembly; wherein the probe head assembly includes a plurality sets of probes that are vertical probes, for transmitting the high frequency signal to a silicon substrate; and
processing the high frequency signal into an output signal using a signal processing circuit on the silicon substrate, and transmitting the output signal to a tester.
